(19) United States
(12) Patent Application Publication
(10) Pub. No.: US 2015/0086764 A1
(43) Pub. Date: Mar. 26, 2015

(54) METHOD OF FORMING A COMPOSITE CHASSIS MATERIAL USING A BIOPOLYMER

(71) Applicants: Andrea Weinert Falkin, Austin, TX (US); Deeder M. Aurongzeb, Round Rock, TX (US)

(72) Inventors: Andrea Weinert Falkin, Austin, TX (US); Deeder M. Aurongzeb, Round Rock, TX (US)

(21) Appl. No.: 14/038,021

(22) Filed: Sep. 26, 2013

(51) Int. Cl. H05K 5/02; B32B 5/02; B32B 5/24; B32B 37/24

(52) U.S. Cl. CPC H05K 5/02; B32B 37/24; B32B 5/024; B32B 5/245; B32B 2037/243; B32B 2037/246; B32B 2255/26; B32B 2307/3065; B32B 2457/00
USPC 428/213; 156/280; 156/308.2; 442/224; 428/220; 428/317.9

(57) ABSTRACT

Methods for manufacturing a composite chassis material using a biopolymer may be used to provide high-strength, low weight, and flame retardant structural elements in information handling systems. A method for manufacturing the composite chassis material using a biopolymer may include selectively adding silica, such as silica fume and/or silica nanoparticles, and pre-forming a biopolymer foam core that is coated with a polysulphonic compound.

### BACKGROUND

1. Field of the Disclosure

This disclosure relates generally to information handling systems and, more particularly, to a composite chassis material using a biopolymer for information handling systems.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Advancements in packaging design have reduced both the weight and thickness of information handling systems. Additionally, market conditions increasingly favor the use of environmentally friendly and/or sustainable materials in information handling systems. One such class of materials are biopolymers, which refers to polymers produced by living organisms, such as, for example, cellulose. The inclusion of biopolymer content in chassis materials for information handling systems has been constrained by the challenge of meeting desired mechanical and safety criteria, such as flame retardance.

Accordingly, it is desirable to have an improved design and a correspondingly improved manufacturing method for structural components in an information handling system that include environmentally friendly materials, such as biopolymers, yet meet conventional safety criteria for computer products, including flame redundancy criteria.

### SUMMARY

In one aspect, a disclosed method of manufacturing a composite chassis material using a biopolymer for use in an information handling system may include impregnating a first carbon fiber weave with a thermoplastic resin to form a first carbon fiber layer, forming a biopolymer foam core by laminating the first carbon fiber layer with a biopolymer sheet and a silica material, and applying a coating of a polysulphonic compound to the biopolymer foam core to form a flame retardant laminate. The method may further include laminating the flame retardant laminate with a second carbon fiber layer, and applying pressure and heat via the first carbon fiber layer and the second carbon fiber layer to form the composite chassis material.

Other disclosed aspects include a composite chassis material using a biopolymer for use in an information handling system, including at least one biopolymer foam core, and a polysulphonic compound coated on the at least one biopolymer foam core. The at least one biopolymer foam core may include a first fiber layer and a first thermoplastic resin, a biopolymer sheet, and a silica material.

### BRIEF DESCRIPTION OF THE DRAWINGS

For a more complete understanding of the present invention and its features and advantages, reference is now made to the following description, taken in conjunction with the accompanying drawings, in which:

FIG. 1 is a block diagram of selected elements of an embodiment of an information handling system;

FIGS. 2A, 2B, and 2C show selected elements of embodiments of different types of information handling systems including a composite chassis material using a biopolymer; and

FIG. 3 is flowchart depicting selected elements of an embodiment of a method for manufacturing a composite chassis material using a biopolymer for use in an information handling system.

### DESCRIPTION OF PARTICULAR EMBODIMENT(S)

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components or the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such wires, optical fibers, microwaves, radio waves, and other electromagnetic and/or optical carriers; and/or any combination of the foregoing.

As noted previously, current information handling systems may demand ever thinner and lighter products, without sacrificing strength and stability. Furthermore, the use of environmentally friendly biopolymer materials is desired without undesirable flame retardant properties. As will be described in further detail, the inventors of the present disclosure have developed novel methods and structures disclosed herein for manufacturing a composite chassis material using a biopolymer for structural use in information handling systems that provides high strength, low weight, and desirable levels of flame retardance.

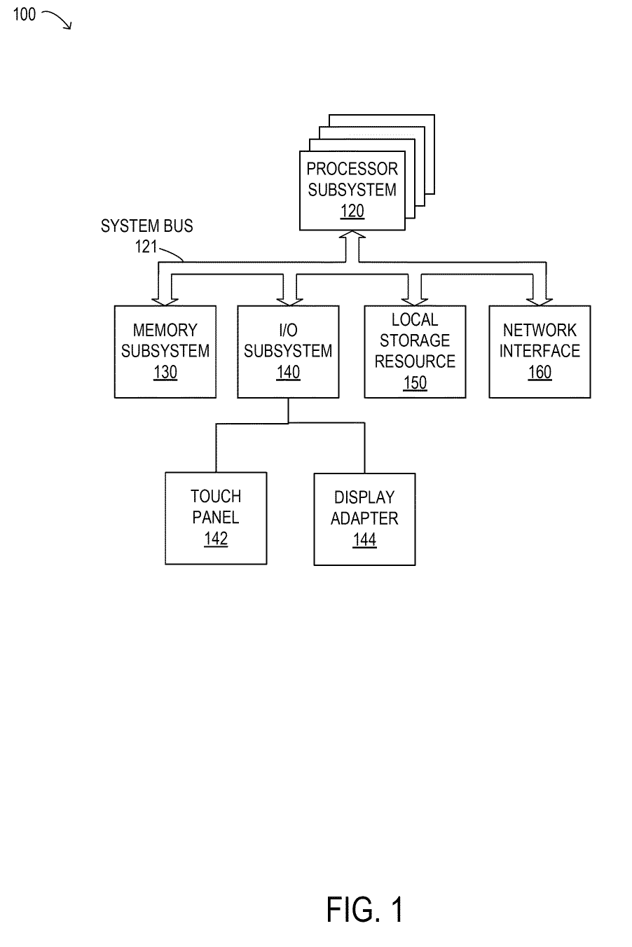

Particular embodiments are best understood by reference to FIGS. 1, 2A, 2B, and 3 wherein like numbers are used to indicate like and corresponding parts.

Turning now to the drawings, FIG. 1 illustrates a block diagram depicting selected elements of an embodiment of information handling system 100. As shown in FIG. 1, components of information handling system 100 may include, but are not limited to, processor subsystem 120, which may comprise one or more processors, and system bus 121 that communicatively couples various system components to processor subsystem 120 including, for example, a memory subsystem 130, an I/O subsystem 140, local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

In FIG. 1, network interface 160 may be a suitable system, apparatus, or device operable to serve as an interface between information handling system 100 and a network 155. Network interface 160 may enable information handling system 100 to communicate over network 155 using a suitable transmission protocol and/or standard, including, but not limited to, transmission protocols and/or standards enumerated below with respect to the discussion of network 155. In some embodiments, network interface 160 may be communicatively coupled via network 155 to network storage resource 170. Network 155 may be implemented as, or may be a part of, a storage area network (SAN), personal area network (PAN), local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network 155 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 155 and its various components may be implemented using hardware, software, or any combination thereof.

As depicted in FIG. 1, processor subsystem 120 may comprise a system, device, or apparatus operable to interpret and/or execute program instructions and/or process data, and may include a microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of physical hardware 102). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down. Local storage resource 150 may comprise computer-readable media (e.g., hard disk drive, floppy disk drive, CD-ROM, and/or other type of rotating storage media, flash memory, EEPROM, and/or another type of solid state storage media) and may be generally operable to store instructions and/or data. Likewise, network storage resource 170 may comprise computer-readable media (e.g., hard disk drive, floppy disk drive, CD-ROM, and/or other type of rotating storage media, flash memory, EEPROM, and/or other type of solid state storage media) and may be generally operable to store instructions and/or data. In system 100, I/O subsystem 140 may comprise a system, device, or apparatus generally operable to receive and/or transmit data to/from/within system 100. I/O subsystem 140 may represent, for example, a variety of communication interfaces, graphics interfaces, video interfaces, user input interfaces, and/or peripheral interfaces. As shown, I/O subsystem 140 may comprise touch panel 142 and display adapter 144. Touch panel 142 may include circuitry for enabling touch functionality in conjunction with a display for (not shown) that is driven by display adapter 144.

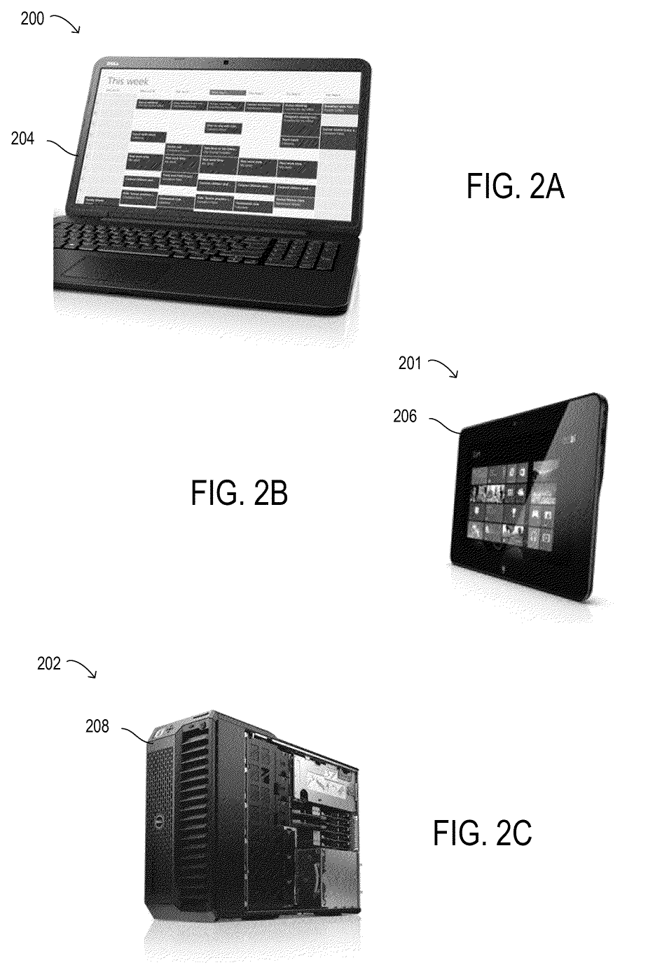

Turning now to FIG. 2A, selected elements of an embodiment of portable information handling system 200 are illustrated. In FIG. 2A, portable information handling system 200 is shown as a laptop computer with integrated display and keyboard. As shown, portable information handling system 200 may include chassis 204, which may be formed, at least in part, using a composite chassis material including a biopolymer, as described herein. It is noted that chassis 204 may comprise a number of individual parts and components of different types of materials, of which certain elements and aspects may be obscured from view in FIG. 2A. The composite chassis material including a biopolymer, as disclosed herein, may be used for a variety of parts and components of chassis 204.

Turning now to FIG. 2B, selected elements of an embodiment of portable information handling system 201 are illustrated. In FIG. 2B, portable information handling system 201 is shown as a tablet computer with integrated display and touch screen. As shown, portable information handling system 201 may include chassis 206, which may be formed, at least in part, using a composite chassis material including a biopolymer, as described herein. It is noted that chassis 206 may comprise a number of individual parts and components of different types of materials, of which certain elements and aspects may be obscured from view in FIG. 2B. The composite chassis material including a biopolymer, as disclosed herein, may be used for a variety of parts and components of chassis 206.

Turning now to FIG. 2C, selected elements of an embodiment of information handling system 202 are illustrated. In FIG. 2C, portable information handling system 202 is shown as a server and/or desktop computer. As shown, information handling system 202 may include chassis 208, which may be formed, at least in part, using a composite chassis material including a biopolymer, as described herein. It is noted that chassis 208 may comprise a number of individual parts and components of different types of materials, of which certain elements and aspects may be obscured from view in FIG. 2C. The composite chassis material including a biopolymer, as disclosed herein, may be used for a variety of parts and components of chassis 208.

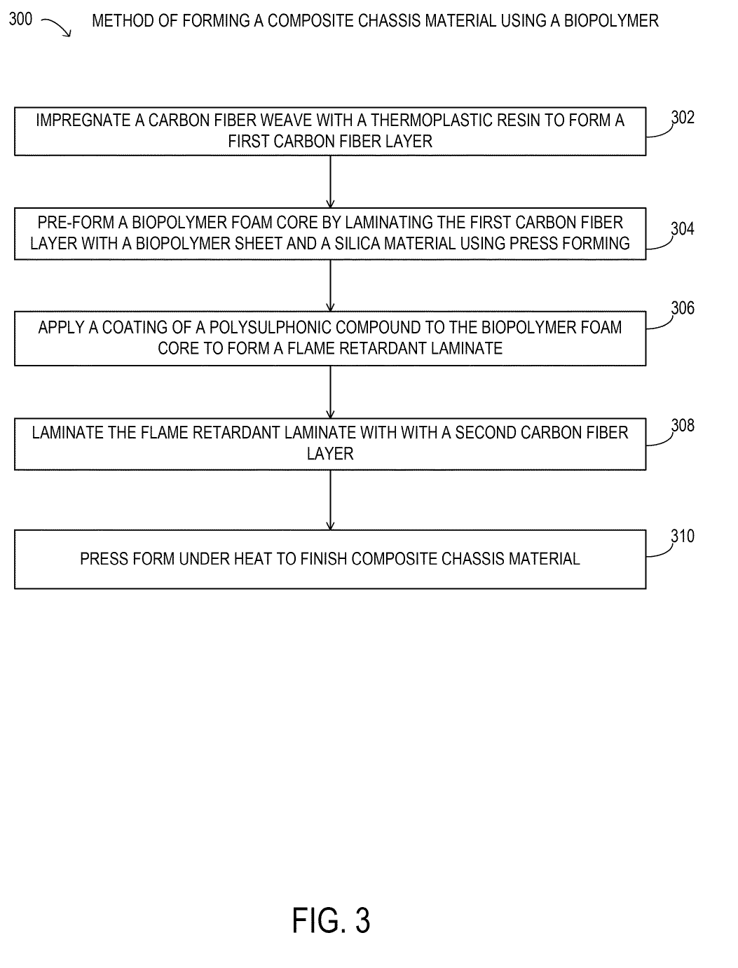

Referring now to FIG. 3, a block diagram of selected elements of an embodiment of method 300 for manufacturing a composite chassis material using a biopolymer for use in an information handling system (such as any one of information handling systems 200, 201, and 202, see FIGS. 2A, 2B, and 2C) is depicted in flowchart form. It is noted that certain operations described in method 300 may be optional or may be rearranged in different embodiments. It is noted that, unless otherwise noted, the values given below for percentage by weight composition are in reference to an overall weight of the composite chassis material.

Method 300 may begin by impregnating (operation 302) a carbon fiber weave with a thermoplastic resin to form a first carbon fiber layer. In one embodiment, the carbon fiber weave used in operation 302 may be so-called “3K” weave having about 3000 filaments per roving that are interwoven to result in a carbon fiber fabric. The carbon fiber weave may be cut to a desired shape prior to impregnation in operation 302. Then, a biopolymer foam core may be pre-formed (operation 304) by laminating the first carbon fiber layer with a biopolymer sheet and a silica material using press forming. In operation 304, the biopolymer sheet may be between about 0.1 mm and 1 mm thick and may have biological (i.e., organic) content of about 20-60% by weight of the biopolymer sheet. In one embodiment, the biopolymer sheet is 0.2 mm thick and has organic content of about 30% by weight of the biopolymer sheet. Also in some embodiments of operation 304, the silica material may include silica fume of less than about 50% by weight. In a particular embodiment, 20% by weight silica fume is added. In different embodiments, particularly when high-strength carbon fiber is used and a certain reduction in flexibility of the composite chassis material is tolerable, up to about 80% by weight of the silica material may be used. Silica fume refers to an ultrafine particulate material comprised of spherical particles of amorphous silica dioxide having diameters of less than about 1 micrometer (micron), and may have average diameters of about 150 nm. In various embodiments of operation 304, the silica material used may include at least 2% by weight silica nanofibers to provide additional strength and/or desired mechanical properties. In still other embodiments, the silica material used in operation 304 may be mixed with graphene flakes having a minimum thickness of about 1 nm and a dimensional size greater than about 1 micrometer and may be added from about 2% by weight up to about 50% by weight. The relatively high thermal conductivity of the graphene (greater than about 200 W/mK) added in this manner to the silica material may aid in flame retardance by drawing heat away, for example, from a portion of a composite chassis material that is at a high temperature, and may improve overall cooling properties of the composite chassis material.

Then, a coating of a polysulphonic compound may be applied (operation 306) to the biopolymer foam core to form a flame retardant laminate. The polysulphonic compound may include a polysulphonic acid and may be spray coated or may be vapor deposited in operation 306 and may preferentially adhere to the thermoplastic resin used in operation 302. The polysulphonic compound used in operation 306 may be applied as a dopant (i.e., at a low concentration of about 2% to 5% by liquid volume) and/or in various combinations with classes of non-halogen flame retardants, such as phosphorous-types (also referred to as ‘char-former’ types) and metal oxides (also referred to as ‘endothermic’ types). The phosphorous-based flame retardants may include organic and/or inorganic phosphorous compounds, as well as elemental phosphorous compounds, such as organic phosphates, esters, and/or inorganic phosphates. The coating of the polysulphonic compound (i.e., including a polysulphonic acid) may be applied as a very thin flame retardant barrier, with a thickness of less than about 2% of the part to which the coating is being applied, for example, the biopolymer foam core. Such a sparse, yet effective for flame retardance, application of the polysulphonic compound coating may also add economical value to the composite chassis material by reducing raw material expenses for a given level of flame retardance.

Then, the flame retardant laminate may be laminated (operation 308) with a second carbon fiber layer. It is noted that, in some embodiments, multiple instances of the flame retardant laminate resulting from operation 306 may be layered to form a multilayered or repeating laminate structure, before operation 308 is performed. In various embodiments, the second carbon fiber layer used in operation 308 may be similar or substantially similar to the first carbon fiber layer formed in operation 302. The second carbon fiber layer may be laminated to an opposite surface than the first carbon fiber layer, resulting in a composite chassis material having two external carbon fiber surfaces. Then, the resulting structure from operation 308 may be press formed (operation 310) under heat to finish the composite chassis material. The press forming in operation 310 may be performed at a temperature of about 200 C.

The composite chassis material formed using method 300, as described above, may result in a structure that contains a significant composition of biopolymer and has sufficient mechanical strength and structural robustness for use in portable and/or stationary information handling systems. In various embodiments, the composite chassis material formed using method 300 may have an overall thickness in the range of abut 0.5 mm to 2.0 mm. Furthermore, the composite chassis material formed using method 300 may exhibit good flame retardance due to various factors. For example, the decomposition of the polysulphonic compound under heat (e.g., exposure to flame) may locally produce sulfur gas, which may inhibit oxygen from reaching a surface of the composite chassis material. Also, the solid phase compositional loading with the silica material (e.g., silica fume, silica nanoparticles, and/or graphene flakes) may further improve the flame retardance of the composite chassis material during exposure to flame. Although method 300 is described using carbon fiber, it is noted that, in different embodiments, method 300 may be adapted to used aramid fiber, glass fiber, alumina based ceramic fiber, and/or other types of polymeric or composite fibers generally having a melting point greater than about 200 C.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method for manufacturing a composite chassis material using a biopolymer for use in an information handling system, comprising:
impregnating a first carbon fiber weave with a thermoplastic resin to form a first carbon fiber layer;
forming a biopolymer foam core by laminating the first carbon fiber layer with a biopolymer sheet and a silica material; and
applying a coating of a polysulphonic compound to the biopolymer foam core to form a flame retardant laminate.

2. The method of claim 1, wherein the biopolymer sheet has a thickness between 0.1 mm and 1.0 mm and includes 30% by weight organic content.

3. The method of claim 1, wherein the coating of the polysulphonic compound less than 2% of the thickness of the biopolymer foam core.

4. The method of claim 1, wherein the silica material includes at least one of: silica fume, silica nanofibers, and graphene flakes.

5. The method of claim 1, wherein multiple instances of the flame retardant laminate are used to form a repeating multilayered composite structure.

6. The method of claim 1, wherein the silica material represents 20% by weight of the composite chassis material.

7. The method of claim 1, wherein applying the coating of the polysulphonic compound includes at least one of: spray coating and vapor coating.

8. The method of claim 1, wherein forming the biopolymer foam core includes applying pressure and heat.

9. The method of claim 1, wherein the first carbon fiber weave is a 3K carbon fiber weave.

10. The method of claim 1, further comprising:
laminating the flame retardant laminate with a second carbon fiber layer; and
applying pressure and heat via the first carbon fiber layer and the second carbon fiber layer to form the composite chassis material.

11. The method of claim 10, wherein the heat corresponds to a temperature of 200 C.

12. The method of claim 10, wherein the second carbon fiber layer includes:
a 3K carbon fiber weave; and
a thermoplastic resin.

13. A composite chassis material comprising:
at least one biopolymer foam core, including:
a first carbon fiber layer including a first carbon fiber weave and a first thermoplastic resin;
a biopolymer sheet; and
a silica material;
a polysulphonic compound coated on the at least one biopolymer foam core; and
a second carbon fiber layer including a second carbon fiber weave and a second thermoplastic resin.

14. The composite chassis material of claim 13, wherein a thickness of the polysulphonic compound is less than 2% of the thickness of the biopolymer foam core.

15. The composite chassis material of claim 13, wherein the biopolymer sheet has a thickness of between 0.1 mm and 1.0 mm and the composite chassis material has a thickness of 0.5 mm to 2.0 mm.

16. The composite chassis material of claim 13, wherein the biopolymer sheet includes 30% by weight organic content.

17. The composite chassis material of claim 13, wherein the silica material includes at least one of: silica fume, silica nanofibers, and graphene flakes.

18. A composite chassis material comprising:
at least one biopolymer foam core, including:
a first fiber layer including a first thermoplastic resin;
a biopolymer sheet; and
a silica material; and
a polysulphonic compound coated on the at least one biopolymer foam core.

19. The composite chassis material of claim 18, wherein the first fiber layer has a melting point greater than 200 C and comprises at least one of: carbon fiber, aramid fiber, glass fiber, alumina based ceramic fiber, and a polymeric fiber.

20. The composite chassis material of claim 18, wherein a thickness of the polysulphonic compound is less than 2% of the thickness of the biopolymer foam core, and wherein the silica material includes at least one of: silica fume, silica nanofibers, and graphene flakes.
